(19) United States
(12) Patent Application Publication
(10) Pub. No.: US 2024/0324300 A1
(43) Pub. Date: Sep. 26, 2024

(54) DISPLAY DEVICE

(71) Applicant: Samsung Display Co., LTD., Yongin-si (KR)

(72) Inventors: SANG MIN HONG, Yongin-si (KR); HYOMIN KIM, Yongin-si (KR); NARI HEO, Yongin-si (KR)

(21) Appl. No.: 18/410,520

(22) Filed: Jan. 11, 2024

(30) Foreign Application Priority Data
Mar. 24, 2023 (KR) 10-2023-0038608

(51) Int. Cl. H10K 59/122; H10K 59/80

(52) U.S. Cl. CPC H10K 59/122; H10K 59/8791

(57) ABSTRACT

A display device includes: a substrate including a first light emitting area, a second light emitting area, and a third light emitting area, and a light blocking area positioned between the first, second, and third light emitting areas; a first light emitting layer disposed in the first light emitting area on the substrate and which emits light of a first color; a second light emitting layer disposed in the second light emitting area on the substrate, including an upper surface having a curved shape in a cross-section, and which emits light of a second color different from the first color; a third light emitting layer disposed in the third light emitting area on the substrate and which emits light of a third color different from the first and second colors; and a reflection control layer disposed on the first, second, and third light emitting layers.

This application claims priority to Korean Patent Application No. 10-2023-0038608, filed on Mar. 24, 2023 and all the benefits accruing therefrom under 35 U.S.C. § 119, the content of which in its entirety is herein incorporated by reference.

### BACKGROUND

### 1. Technical Field

Embodiments provide generally to a display device. More particularly, embodiments relate to a display device that provides visual information.

### 2. Description of the Related Art

As information technology develops, the importance of a display device, which is communication media between users and information, is being highlighted. Accordingly, the use of the display device such as a liquid crystal display device, an organic light emitting display device, a plasma display device, and the like is increasing.

Meanwhile, since the display device includes lines and electrodes including metal, external light incident on the display device may be reflected from the lines and electrodes. In order to prevent reflection by external light, the display device generally includes a polarizer. However, the polarizer can prevent reflection by external light, but light efficiency of the display device can be reduced due to the polarizer.

### SUMMARY

Embodiments provide a display device with improved display quality.

A display device according to embodiments of the present disclosure include: a substrate including a first light emitting area, a second light emitting area, and a third light emitting area, and a light blocking area positioned between the first, second, and third light emitting areas; a first light emitting layer disposed in the first light emitting area on the substrate and which emits light of a first color; a second light emitting layer disposed in the second light emitting area on the substrate, including an upper surface having a curved shape in a cross-section, and which emits light of a second color different from the first color; a third light emitting layer disposed in the third light emitting area on the substrate and which emits light of a third color different from the first and second colors; and a reflection control layer disposed on the first, second, and third light emitting layers.

In an embodiment, an edge of the upper surface of the second light emitting layer may be inclined with respect to a major upper surface of the substrate.

In an embodiment, the upper surface of the second light emitting layer may have a concave shape or a convex shape in the cross-section.

In an embodiment, each of the first and third light emitting layers may have a substantially flat upper surface.

In an embodiment, the display device may further include a first pixel electrode disposed in the first light emitting area between the substrate and the first light emitting layer, a second pixel electrode disposed in the second light emitting area between the substrate and the second light emitting layer, and a third pixel electrode disposed in the third light emitting area between the substrate and the third light emitting layer. The second pixel electrode may have an upper surface having a curved shape in the cross-section.

In an embodiment, the display device may further include a via-insulating layer disposed between the substrate and the first, second, and third pixel electrodes. In the second light emitting area, the via-insulating layer may include a protruding part protruding toward the second pixel electrode at an upper surface of the via-insulating layer.

In an embodiment, the display device may further include a via-insulating layer disposed between the substrate and the first, second, and third pixel electrodes. In the second light emitting area, the via-insulating layer may include a depressed part depressed toward the substrate at an upper surface of the via-insulating layer.

In an embodiment, the display device may further include: a first transistor electrically connected to the first pixel electrode and including a first active pattern, a first gate electrode, a first source electrode, and a first drain electrode; a second transistor electrically connected to the second pixel electrode and including a second active pattern, a second gate electrode, a second source electrode, and a second drain electrode; and a third transistor electrically connected to the third pixel electrode and including a third active pattern, a third gate electrode, a third source electrode, and a third drain electrode.

In an embodiment, when the second source electrode and the second drain electrode at least partially overlap the second light emitting layer in a plan view, a thickness of each of the second source electrode and the second drain electrode may be different from a thickness of each of the first source electrode, the first drain electrode, the third source electrode, and the third drain electrode.

In an embodiment, when the second gate electrode at least partially overlap the second light emitting layer, a thickness of the second gate electrode may be different from a thickness of each of the first and third gate electrodes.

In an embodiment, when the second active pattern at least partially overlap the second light emitting layer, a thickness of the second active pattern may be different from a thickness of each of the first and third active patterns.

In an embodiment, the first color may be red, the second color may be green, and the third color may be blue.

In an embodiment, the reflection control layer may include an inorganic material or an organic material containing at least one selected from a group consisting of dye and pigment.

In an embodiment, the display device may further include a reflection reducing inorganic layer disposed on the first, second, and third light emitting layers and including an inorganic material.

In an embodiment, the display device may further include an encapsulation layer disposed on the first, second, and third light emitting layers and including: a first inorganic encapsulation layer including sequentially disposed first, second, third, and fourth sub-layers, an organic encapsulation layer disposed on the first inorganic encapsulation layer, and a second inorganic encapsulation layer disposed on the organic encapsulation layer.

In an embodiment, the first sub-layer may include silicon nitride, each of the second, third, and fourth sub-layers may include silicon oxynitride, and the second inorganic encapsulation layer may include silicon oxynitride.

In an embodiment, the display device may further include a light blocking layer disposed in the light blocking area on the substrate and covered by the reflection control layer.

A display device according to embodiments of the present disclosure include: a substrate including a first light emitting area, a second light emitting area, and a third light emitting area, and a light blocking area positioned between the first, second, and third light emitting areas; a first light emitting layer disposed in the first light emitting area on the substrate, including a substantially flat upper surface, and which emits light of a red color; a second light emitting layer disposed in the second light emitting area on the substrate, including an upper surface having a curved shape in a cross-section, and which emits light of a green color; a third light emitting layer disposed in the third light emitting area on the substrate, including a substantially flat upper surface, and which emits light of a blue color; an encapsulation layer disposed on the first, second, and third light emitting layers; a touch sensing layer disposed on the encapsulation layer and including a first touch electrode and a second touch electrode connected to the first touch electrode; and a reflection control layer disposed on the touch sensing layer.

In an embodiment, an edge of the upper surface of the second light emitting layer may be inclined with respect to a major upper surface of the substrate.

In an embodiment, the upper surface of the second light emitting layer may have a concave shape or a convex shape in the cross-section.

In a display device according to embodiments, an upper surface of a second light emitting layer that emits green light may have a curved shape in a cross-section, and an upper surface of each of a first light emitting layer that emits red light and a third light emitting layer that emits blue light may be substantially flat. Accordingly, the amount of light emitted from the second light emitting layer at a low angle can be increased, and the color of an image displayed in a display area can be prevented from reddish. In this case, display quality of the display device can be effectively improved.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is a cross-sectional view taken along line I-I′ of FIG. 1.

FIG. 3 is a cross-sectional view for explaining an encapsulation layer of FIG. 2.

FIGS. 4, 5, 6, 7, 8, and 9 are cross-sectional views for explaining a method for manufacturing the display device of FIG. 2.

FIG. 10 is a cross-sectional view illustrating a display device according to another embodiment of the present disclosure.

FIG. 11 is a cross-sectional view illustrating a display device according to still another embodiment of the present disclosure.

FIG. 12 is a cross-sectional view illustrating a display device according to still another embodiment of the present disclosure.

FIG. 13 is a cross-sectional view illustrating a display device according to still another embodiment of the present disclosure.

FIG. 14 is a cross-sectional view illustrating a display device according to still another embodiment of the present disclosure.

FIG. 15 is a cross-sectional view illustrating a display device according to still another embodiment of the present disclosure.

### DETAILED DESCRIPTION

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “substantially flat” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially flat” can mean within one or more standard deviations, or within ±20%, 10% or 5% of a perfect flatness.

Hereinafter, a display device according to embodiments of the present disclosure will be explained in detail with reference to the accompanying drawings. The same reference numerals are used for the same components in the drawings, and redundant descriptions of the same components will be omitted.

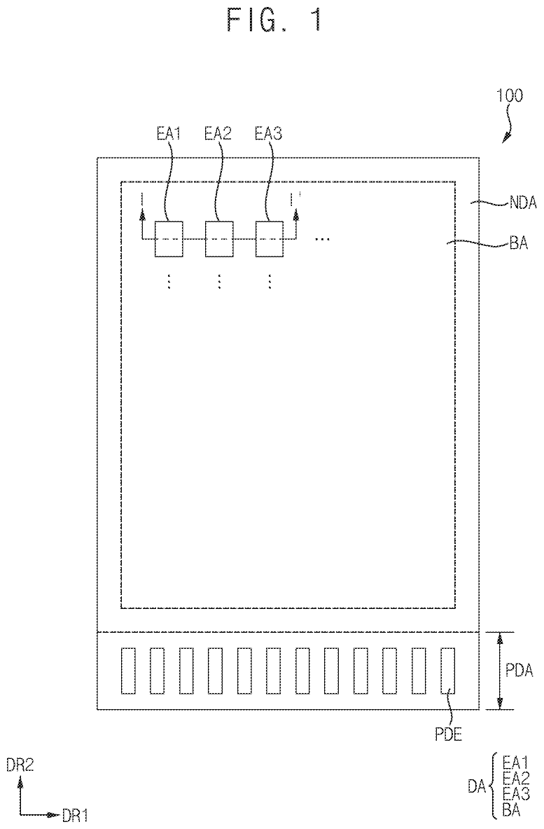

FIG. 1 is a plan view illustrating a display device according to an embodiment of the present disclosure. As used herein, the “plan view” is a view in a thickness direction of the substrate.

Referring to FIG. 1, a display device 100 according to an embodiment may include a display area DA and a non-display area NDA. The display area DA may be an area capable of displaying an image by generating light or adjusting transmittance of light provided from an external light source. The non-display area NDA may be an area not displaying an image. The non-display area NDA may be positioned around the display area DA. In an embodiment, for example, the non-display area NDA may surround the entirety of the display area DA.

The display area DA may include a plurality of light emitting areas and a light blocking area BA. Each of the light emitting areas may refer to an area in which light emitted from a light emitting element is emitted to the outside of the display device 100. As the light emitting areas emit light, the display area DA may display an image. For example, the light emitting regions may be arranged in a matrix form along a first direction DR1 and a second direction DR2 crossing the first direction DR1.

The light emitting areas may include a first light emitting area EA1, a second light emitting area EA2, and a third light emitting area EA3. In an embodiment, for example, the first light emitting area EAT may emit first light, the second light emitting area EA2 may emit second light, and the third light emitting area EA3 may emit third light. In an embodiment, the first light may be red light, the second light may be green light, and the third light may be blue light. However, embodiments of the present disclosure are not limited thereto. In another embodiment, for example, the first, second, and third light emitting areas EAT, EA2, and EA3 may be combined to emit yellow, cyan, and magenta lights.

The first, second, and third light emitting areas EA1, EA2, and EA3 may emit light of four or more colors. For example, the first, second, and third light emitting areas EA1, EA2, and EA3 may be combined to further emit at least one of yellow, cyan, and magenta lights in addition to red, green, and blue lights. In addition, the first, second, and third light emitting areas EAT, EA2, and EA3 may be combined to further emit white light.

Each of the first light emitting area EAT, the second light emitting area EA2, and the third light emitting area EA3 may have a triangular planar shape, a quadrangular planar shape, a circular planar shape, an elliptical planar shape, or the like. In an embodiment, each of the first light emitting area EAT, the second light emitting area EA2, and the third light emitting area EA3 may have a rectangular planar shape. However, the embodiments of the present disclosure are not limited thereto, and each of the first light emitting area EAT, the second light emitting area EA2, and the third light emitting area EA3 may have a different planar shape in another embodiment.

The light blocking area BA may be positioned between the first light emitting area EAT, the second light emitting area EA2, and the third light emitting area EA3. For example, in a plan view, the light blocking area BA may surround the first light emitting area EAT, the second light emitting area EA2, and the third light emitting area EA3. The light blocking area BA may not emit light.

The non-display area NDA may include a pad area PDA. The pad area PDA may be spaced apart from one side of the display area DA. In an embodiment, for example, the pad area PDA may have a shape extending in the first direction DRT.

A plurality of lines may be disposed in the non-display area NDA, and a plurality of pad electrodes PDE may be disposed in the pad area PDA. The lines may electrically connect the pad electrodes PDE and the light emitting areas. For example, the lines may include data signal lines, scan signal lines, light emitting control signal lines, power supply voltage lines, or the like.

The pad electrodes PDE may be disposed to be spaced apart from each other in the first direction DRT. In an embodiment, for example, each of the pad electrodes PDE may include a metal, an alloy, a metal nitride, a conductive metal oxide, a transparent conductive material, or the like. These may be used alone or in combination with each other.

In this specification, a plane may be defined as the first direction DRT and the second direction DR2 crossing the first direction DR1. For example, the first direction DR1 may be perpendicular to the second direction DR2.

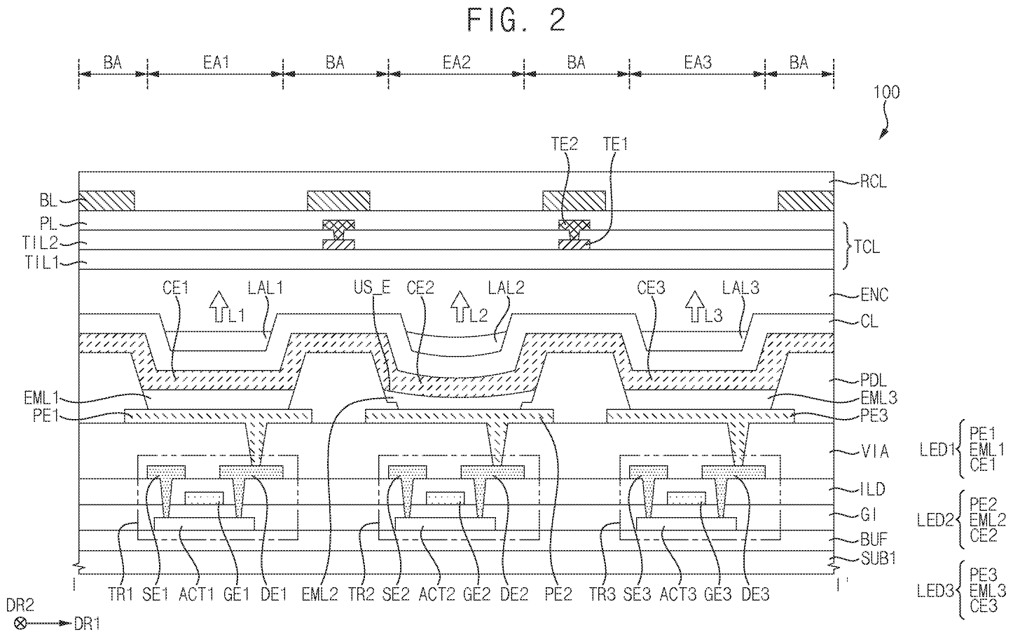

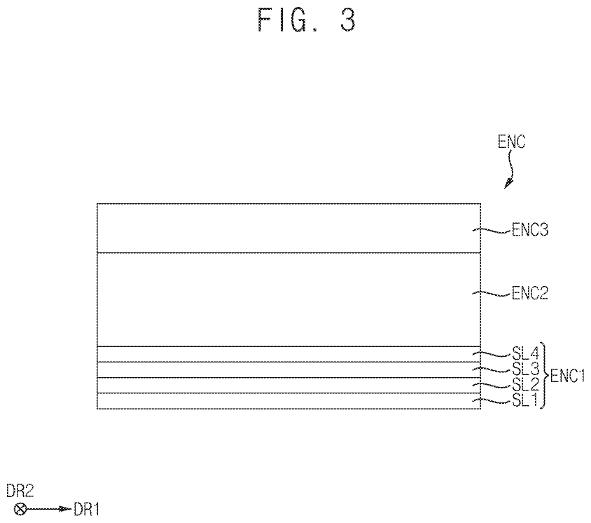

FIG. 2 is a cross-sectional view taken along line I-I′ of FIG. 1. FIG. 3 is a cross-sectional view for explaining an encapsulation layer of FIG. 2.

Referring to FIGS. 2 and 3, the display device 100 according to an embodiment of the present disclosure may include a substrate SUB, a buffer layer BUF, a gate insulating layer GI, first, second, and third transistors TR1, TR2, and TR3, an interlayer-insulating layer ILD, a via-insulating layer VIA, a pixel defining layer PDL, first, second, and third light emitting elements LED1, LED2, and LED3, a capping layer CL, first, second, and third low-reflection inorganic layers LAL1, LAL2, and LAL3, an encapsulation layer ENC, a touch sensing layer TCL, a light blocking layer BL, and a reflection control layer RCL.

Here, the first transistor TR1 may include a first active pattern ACT1, a first gate electrode GEL, a first source electrode SE1, and a first drain electrode DE1, the second transistor TR2 may include a second active pattern ACT2, a second gate electrode GE2, a second source electrode SE2, and a second drain electrode DE2, and the third transistor TR3 may include a third active pattern ACT3, a third gate electrode GE3, a third source electrode SE3, and a third drain electrode DE3.

In addition, the first light emitting element LED1 may include a first pixel electrode PET, a first light emitting layer EML1, and a first common electrode CET, the second light emitting element LED2 may include a second pixel electrode PE2, a second light emitting layer EML2, and a second common electrode CE2, the third light emitting element LED3 may include a third pixel electrode PE3, a third light emitting layer EML3, and a third common electrode CE3.

As described above, the display device 100 may include the first, second, and third light emitting areas EA1, EA2, and EA3 and the light blocking area BA. As the display device 100 includes the first, second, and third light emitting areas EAT, EA2, and EA3 and the light blocking area BA, components (e.g., the substrate SUB) included in the display device 100 may also include the first, second, and third light emitting areas EA1, EA2, and EA3 and the light blocking area BA.

The substrate SUB may include a transparent material or an opaque material. The substrate SUB may be made of a transparent resin substrate. Examples of the transparent resin substrate may include polyimide substrates and the like. In this case, the polyimide substrate may include a first organic layer, a first barrier layer, and a second organic layer. Alternatively, the substrate SUB may include a quartz substrate, a synthetic quartz substrate, a calcium fluoride substrate, an F-doped quartz substrate, a soda-lime glass substrate, a non-alkali glass substrate, or the like. These may be used alone or in combination with each other.

The buffer layer BUF may be disposed on the substrate SUB. The buffer layer BUF may prevent diffusion of metal atoms or impurities from the substrate SUB into the first, second, and third transistors TR1, TR2, and TR3. In addition, the buffer layer BUF may improve flatness of the surface of the substrate SUB when the surface of the substrate SUB is not uniform. In an embodiment, for example, the buffer layer BUF may include an inorganic material such as silicon oxide, silicon nitride, silicon oxynitride, or the like. These may be used alone or in combination with each other.

The first, second, and third active patterns ACT1, ACT2, and ACT3 may be disposed on the buffer layer BUF. Each of the first, second, and third active patterns ACT1, ACT2, and ACT3 may include a metal oxide semiconductor, an inorganic semiconductor (e.g., amorphous silicon, poly silicon), or an organic semiconductor.

Each of the first, second, and third active patterns ACT1, ACT2, and ACT3 may include a source region, a drain region, and a channel region positioned between the source region and the drain region. The first, second, and third active patterns ACT1, ACT2, and ACT3 may be formed through the same process and include the same material.

The metal oxide semiconductor may include a two-component compound (ABₓ), a ternary compound (ABₓC_{y}), a four-component compound (ABₓCyDz), or the like containing indium (In), zinc (Zn), gallium (Ga), tin (Sn), titanium (Ti), aluminum (Al), hafnium (Hf), zirconium (Zr), magnesium (Mg), or the like. In an embodiment, for example, the metal oxide semiconductor may include zinc oxide (ZnOx), gallium oxide (GaOx), tin oxide (SnOx), indium oxide (InOx), indium gallium oxide (“IGO”), indium zinc oxide (“IZO”), indium tin oxide. (“ITO”), indium zinc tin oxide (“IZTO”), indium gallium zinc oxide (“IGZO”), or the like. These may be used alone or in combination with each other.

The gate insulating layer GI may be disposed on the buffer layer BUF. The gate insulating layer GI may sufficiently cover the first, second, and third active patterns ACT1, ACT2, and ACT3, and may have a substantially flat upper surface without creating a step around the first, second, and third active patterns ACT1, ACT2, and ACT3. Alternatively, the gate insulating layer GI may cover the first, second, and third active patterns ACT1, ACT2, and ACT3 and may be disposed along the profile of each of the first, second, and third active patterns ACT1, ACT2, and ACT3 to have a uniform thickness. In an embodiment, for example, the gate insulating layer GI may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), or the like. These may be used alone or in combination with each other.

The first, second, and third gate electrodes GE1, GE2, and GE3 may be disposed on the gate insulating layer GI. The first gate electrode GE1 may overlap the channel region of the first active pattern ACT1, the second gate electrode GE2 may overlap the channel region of the second active pattern ACT2, and the third gate electrode GE3 may overlap the channel region of the third active pattern ACT3.

Each of the first, second, and third gate electrodes GE1, GE2, and GE3 may include a metal, an alloy metal nitride, a conductive metal oxide, a transparent conductive material, or the like. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), or the like. Examples of the conductive metal oxide may include indium tin oxide, indium zinc oxide, or the like. In addition, examples of the metal nitride may include aluminum nitride (AlNₓ), tungsten nitride (WNₓ), chromium nitride (CrNₓ), or the like. These may be used alone or in combination with each other.

The first, second, and third gate electrodes GE1, GE2, and GE3 may be formed through the same process and include the same material.

The interlayer-insulating layer ILD may be disposed on the gate insulating layer GI. The interlayer-insulating layer ILD may sufficiently cover the first, second, and third gate electrodes GE1, GE2, and GE3 and may have a substantially flat upper surface without creating a step around the first, second, and third gate electrodes GE1, GE2, and GE3. Alternatively, the interlayer-insulating layer ILD may cover the first, second, and third gate electrodes GE1, GE2, and GE3 and may be disposed along the profile of each of the first, second, and third gate electrodes GE1, GE2, and GE3 to have a uniform thickness. In an embodiment, for example, the interlayer-insulating layer ILD may include an inorganic material such as silicon oxide, silicon nitride, silicon carbide, silicon oxynitride, silicon oxycarbide, or the like. These may be used alone or in combination with each other.

The first, second, and third source electrodes SE1, SE2, and SE3 may be disposed on the interlayer-insulating layer ILD. The first source electrode SE1 may be connected to the source region of the first active pattern ACT1 through a contact hole penetrating the gate insulating layer GI and the interlayer-insulating layer ILD. The second source electrode SE2 may be connected to the source region of the second active pattern ACT2 through a contact hole penetrating the gate insulating layer GI and the interlayer-insulating layer ILD. The third source electrode SE3 may be connected to the source region of the third active pattern ACT3 through a contact hole penetrating the gate insulating layer GI and the interlayer-insulating layer ILD.

The first, second, and third electrodes DE1, DE2, and DE3 may be disposed on the interlayer-insulating layer ILD. The first drain electrode DE1 may be connected to the drain region of the first active pattern ACT1 through a contact hole penetrating the gate insulating layer GI and the interlayer-insulating layer ILD. The second drain electrode DE2 may be connected to the drain region of the second active pattern ACT2 through a contact hole penetrating the gate insulating layer GI and the interlayer-insulating layer ILD. The third drain electrode DE3 may be connected to the drain region of the third active pattern ACT3 through a contact hole penetrating the gate insulating layer GI and the interlayer-insulating layer ILD.

In an embodiment, for example, each of the first, second, and third source electrodes SET, SE2, and SE3 may include a metal, an alloy, a metal nitride, a conductive metal oxide, a transparent conductive material, or the like. These may be used alone or in combination with each other. The first, second, and third drain electrodes DE1, DE2, and DE3 may be formed through the same process as the first, second, and third source electrodes SET, SE2, and SE3 and may include the same material.

Accordingly, the first transistor TR1 including the first active pattern ACT1, the first gate electrode GET, the first source electrode SE1 and the first drain electrode DE1 may be disposed on the substrate SUB. The second transistor TR2 including the second active pattern ACT2, the second gate electrode GE2, the second source electrode SE2, and the second drain electrode DE2 may be disposed on the substrate SUB. The third transistor TR3 including the third active pattern ACT3, the third gate electrode GE3, the third source electrode SE3, and the third drain electrode DE3 may be disposed on the substrate SUB.

The via-insulating layer VIA may be disposed on the interlayer insulation layer ILD. The via-insulating layer VIA may sufficiently cover the first, second, and third source electrodes SET, SE2, and SE3 and the first, second, and third drain electrodes DE1, DE2, and DE3. The via-insulating layer VIA may include an organic material. In an embodiment, for example, the via-insulating layer VIA may include phenolic resin, polyacrylates resin, polyimides rein, polyamides resin, siloxane resin, epoxy resin, or the like. These may be used alone or in combination with each other.

The first, second, and third pixel electrodes PET, PE2, and PE3 may be disposed on the via-insulating layer VIA. The first pixel electrode PET may overlap the first light emitting area EAT, the second pixel electrode PE2 may overlap the second light emitting area EA2, and the third pixel electrode PE3 may overlap the third light emitting area EA3. The first pixel electrode PET may be connected to the first drain electrode DET through a contact hole penetrating the via-insulating layer VIA, the second pixel electrode PE2 may be connected to the second drain electrode DE2 through a contact hole penetrating the via-insulating layer VIA, and the third pixel electrode PE3 may be connected to the third drain electrode DE3 through a contact hole penetrating the via-insulating layer VIA.

In an embodiment, for example, each of the first, second, and third pixel electrodes PET, PE2, and PE3 may include a metal, an alloy, a metal nitride, a conductive metal oxide, a transparent conductive material, or the like. These may be used alone or in combination with each other. In an embodiment, each of the first, second, and third pixel electrodes PET, PE2, and PE3 may have a stacked structure including ITO/Ag/ITO. The first, second, and third pixel electrodes PET, PE2, and PE3 may be formed through the same process and include the same material. For example, each of the first, second, and third pixel electrodes PET, PE2, and PE3 may operate as an anode.

The pixel defining layer PDL may be disposed on the via-insulating layer VIA. The pixel defining layer PDL may overlap the light blocking area BA. The pixel defining layer PDL may cover an edge of each of the first, second, and third pixel electrodes PET, PE2, and PE3. In addition, a pixel opening exposing at least a part of an upper surface of each of the first, second, and third pixel electrodes PET, PE2, and PE3 may be defined in the pixel defining layer PDL.

In an embodiment, for example, the pixel defining layer PDL may include an inorganic material and/or an organic material. In an embodiment, the pixel defining layer PDL may include an organic material such as an epoxy resin, a siloxane resin, or the like. These may be used alone or in combination with each other. In another embodiment, the pixel defining layer PDL may include an inorganic material and/or an organic material containing a black light blocking material.

In an embodiment, in the second light emitting area EA2, the pixel defining layer PDL may include a protruding part that contacts the second pixel electrode PE2 and protrudes toward a center of the pixel opening.

The first light emitting layer EML1 may be disposed on the first pixel electrode PET, the second light emitting layer EML2 may be disposed on the second pixel electrode PE2, and the third light emitting layer EML3 may be disposed on the third pixel electrode PE3. In an embodiment, for example, each of the first, second, and third light emitting layers EML1, EML2, and EML3 may include an organic light emitting material that emits light of a predetermined color.

The first light emitting layer EML1 may include an organic light emitting material that emits light of a first color L1, the second light emitting layer EML2 may include an organic light emitting material that emits light of a second color L2, and the third light emitting layer EML3 may include an organic light emitting material that emits light of a third color L3. In an embodiment, for example, the first color may be red, the second color may be green, and the third color may be blue. However, embodiments of the present disclosure are not limited thereto.

In an embodiment, the second light emitting layer EML2 may include an upper surface USE having a curved shape in a cross-section. Specifically, an edge of the upper surface US_E of the second light emitting layer EML2 may be inclined with respect to a major upper surface of the substrate SUB. That is, the angle between a tangential line at the edge of the upper surface US_E and the major upper surface of the substrate SUB is more than 0 degree (°) and less than 90°. In this case, each of the first and third light emitting layers EML1 and EML3 may have a substantially flat upper surface in the cross-section.

As the second light emitting layer EML2 includes the upper surface US_E having a curved shape in the cross-section, the amount of light emitted from the second light emitting layer EML2 at a low angle (e.g., about +30 degrees and/or about −30 degrees with respect to the upper surface of the substrate SUB1) can be increased. Accordingly, the side luminance ratio of the second light emitting area EA2 can be increased. In this case, it is possible to prevent the color of the image displayed in the display area DA from the low angle from reddish. Here, the low angle denotes a viewing angle.

In an embodiment, for example, the upper surface US_E of the second light emitting layer EML2 may have a concave curved shape in the cross-section. Alternatively, the upper surface US_E of the second light emitting layer EML2 may have a convex curved shape in the cross-section. However, embodiments of the present disclosure are not limited thereto. Alternatively, the upper surface US_E of the second light emitting layer EML2 may include a flat part positioned at the center and substantially flat, and an inclined part positioned at an edge and extending to have a predetermined slope from the flat part.

The first common electrode CE1 may be disposed on the first light emitting layer EML1 and the pixel defining layer PDL, the second common electrode CE2 may be disposed on the second light emitting layer EML2 and the pixel defining layer PDL, and the third common electrode CE3 may be disposed on the third light emitting layer EML3 and the pixel defining layer PDL. The first, second, and third common electrodes CET, CE2, and CE3 may be integrally formed. In an embodiment, for example, each of the first, second, and third common electrodes CET, CE2, and CE3 may include a metal, an alloy, a metal nitride, a conductive metal oxide, a transparent conductive material, or the like. These may be used alone or in combination with each other. The first, second, and third common electrodes CE1, CE2, and CE3 may operate as cathode.

Accordingly, the first light emitting element LED1 including the first pixel electrode PET, the first light emitting layer EML1, and the first common electrode CET may be disposed in the first light emitting area EA1 on the substrate SUB. The second light emitting element LED2 including the second pixel electrode PE2, the second light emitting layer EML2, and the second common electrode CE2 may be disposed in the second light emitting area EA2 on the substrate SUB. The third light emitting element LED3 including the third pixel electrode PE3, the third light emitting layer EML3, and the third common electrode CE3 may be disposed in the third light emitting area EA3 on the substrate SUB.

The first light emitting element LED1 may be electrically connected to the first transistor TRT, the second light emitting element LED2 may be electrically connected to the second transistor TR2, and the third light emitting element LED3 may be electrically connected to the third transistor TR3.

The capping layer CL may be disposed on the first, second, and third common electrodes CET, CE2, and CE3. The capping layer CL may be disposed on the entirety of first, second, and third common electrodes CET, CE2, and CE3. The capping layer CL may serve to protect the first, second, and third common electrodes CET, CE2, and CE3. In an embodiment, for example, the capping layer CL may include an organic material and/or an inorganic material.

The first, second, and third low-reflection inorganic layers LAL1, LAL2, and LAL3 may be disposed on the capping layer CL. The first, second, and third low-reflection inorganic layers LAL1, LAL2, and LAL3 may absorb external light. In addition, the first, second, and third low-reflection inorganic layers LAL1, LAL2, and LAL3 may induce destructive interference between external light reflected from the first, second, and third common electrodes CE1, CE2, and CE3 and external light reflected from the first, second, and third low-reflection inorganic layers LAL1, LAL2, and LAL3. Accordingly, the first, second, and third low-reflection inorganic layers LAL1, LAL2, and LAL3 may reduce external light reflectance of the display device 100 by reducing or blocking light traveling toward the outside of the display device 100. The low-reflection inorganic layers LAL1, LAL2, and LAL3 may be referred to as “reflection-reducing inorganic layers”.

The first low-reflection inorganic layer LAL1 may overlap the first light emitting area EAT, the second low-reflection inorganic layer LAL2 may overlap the second light emitting area EA2, and the third low-reflection inorganic layer LAL3 may overlap the third light emitting area EA3. Alternatively, the first, second, and third low-reflection inorganic layers LAL1, LAL2, and LAL3 may be integrally formed and entirely disposed in the display area DA.

Each of the first, second, and third low-reflection inorganic layers LAL1, LAL2, and LAL3 may include an inorganic material. In an embodiment, for example, each of the first, second, and third low-reflection inorganic layers LAL1, LAL2, and LAL3 may include an inorganic material such as a metal, a silicon compound, a metal oxide, or the like.

Examples of the metal may include silver (Ag), aluminum (Al), magnesium (Mg), chromium (Cr), titanium (Ti), nickel (Ni), gold (Au), tantalum (Ta), copper (Cu), calcium (Ca), cobalt (Co), iron (Fe), molybdenum (Mo), tungsten (W), platinum (Pt), ytterbium (Yb), or the like. Examples of the silicon compound may include silicon oxide (SiO₂), silicon nitride (SiNₓ), or the like. Examples of the metal oxide may include titanium oxide (TiO₂), zirconium oxide (ZrO₂), tantalum oxide (Ta₂O₅), hafnium oxide (HfO₂), aluminum oxide (Al₂O₃), zinc oxide (ZnO), yttrium oxide (Y2O₃), beryllium. oxide (BeO), magnesium oxide (MgO), lead oxide (PbO₂), tungsten oxide (WO₃), or the like. These may be used individually or in combination with each other. Alternatively, each of the first, second, and third low-reflection inorganic layers LAL1, LAL2, and LAL3 may include an inorganic material such as lithium fluoride (LiF), calcium fluoride (CaF₂), magnesium fluoride (MgF₂), cadmium sulfide (CdS), or the like. These may be used alone or in combination with each other.

The encapsulation layer ENC may be disposed on the capping layer CL and the first, second, and third low-reflection inorganic layers LAL1, LAL2, and LAL3. The encapsulation layer ENC may prevent impurities, moisture, and the like from permeating the first, second, and third light emitting elements LED1, LED2, and LED3 from the outside. The encapsulation layer ENC may include at least one inorganic encapsulation layer and at least one organic encapsulation layer.

In an embodiment, for example, the encapsulation layer ENC may include a first inorganic encapsulation layer ENC1, an organic encapsulation layer ENC2 disposed on the first inorganic encapsulation layer ENC1, and a second organic encapsulation layer ENC3 disposed on the organic encapsulation layer ENC2.

In an embodiment, the first inorganic encapsulation layer ENC1 may have a multilayer structure including a first sub-layer SL1, a second sub-layer SL2 disposed on the first sub-layer SL1, a third sub-layer SL3 disposed on the second sub-layer SL2, and a fourth sub-layer SL4 disposed on the third sub-layer SL3. In an embodiment, for example, the first sub-layer SL1 may include silicon nitride, the second sub-layer SL2 may include silicon oxynitride, the third sub-layer SL3 may include silicon oxynitride, and the fourth sub-layer SL4 may include silicon oxynitride.

In an embodiment, for example, the organic encapsulation layer ENC2 may include a cured polymer such as polyacrylate or the like, and the second inorganic encapsulation layer ENC3 may include a silicon compound such as silicon oxynitride or the like.

As the encapsulation layer ENC includes the first inorganic encapsulation layer ENC1, the organic encapsulation layer ENC2, and the second inorganic encapsulation layer ENC3, and the first inorganic encapsulation layer ENC1 has a multilayer structure including four sub-layers, light efficiency of the display device 100 can be improved.

The touch sensing layer TCL may be disposed on the encapsulation layer ENC. The touch sensing layer TCL may function as an input unit of the display device 100. The touch sensing layer TCL may include a first touch insulating layer IL1, a second touch insulating layer IL2, a first touch electrode TE1, a second touch electrode TE2, and a protective layer PL.

The first touch insulating layer TIL1 may be disposed on the encapsulation layer ENC. The first touch insulating layer TIL1 may include an inorganic material or an organic material. In an embodiment, for example, the first touch insulating layer TIL1 may include an inorganic material such as silicon oxide, silicon nitride, or the like. These may be used alone or in combination with each other.

The first touch electrode TE1 may be disposed on the first touch insulating layer TIL1. The first touch electrode TE1 may overlap the light blocking area BA. In an embodiment, for example, the first touch electrode TE1 may include a metal, an alloy, a metal nitride, a conductive metal oxide, a transparent conductive material, or the like. These may be used alone or in combination with each other.

The second touch insulating layer TIL2 may be disposed on the first touch insulating layer TIL1 and the first touch electrode TE1. The second touch insulating layer TIL2 may sufficiently cover the first touch electrode TE1. The second touch insulating layer TIL2 may include an inorganic material or an organic material. In an embodiment, for example, the second touch insulating layer TIL2 may include an inorganic material such as silicon oxide, silicon nitride, or the like. These may be used alone or in combination with each other.

The second touch electrode TE2 may be disposed on the second touch insulating layer TIL2. The second touch electrode TE2 may overlap the light blocking area BA. The second touch electrode TE2 may be connected to the first touch electrode TE1 through a contact hole penetrating the second touch insulating layer TIL2. In an embodiment, for example, the second touch electrode TE2 may include carbon nano tube (“CNT”), transparent conductive oxide, indium tin oxide (ITO), indium gallium zinc oxide (IGZO), zinc oxide (ZnO), graphene, silver nanowire (AgNW), copper (Cu), chromium (Cr), or the like. These may be used alone or in combination with each other.

The first touch electrode TE1 and the second touch electrode TE2 may include the same material. Alternatively, the first touch electrode TE1 and the second touch electrode TE2 may include different materials.

The protective layer PL may be disposed on the second touch insulating layer TIL2 and the second touch electrode TE2. The protective layer PL may sufficiently cover the second touch electrode TE2. The protective layer PL may protect the first touch electrode TE1 and the second touch electrode TE2. The protective layer PL may include an inorganic material or an organic material. In an embodiment, for example, the protective layer PL may include an inorganic material such as silicon oxide, silicon nitride, or the like. These may be used alone or in combination with each other.

The light blocking layer BL may be disposed on the protective layer PL. The light blocking layer BL may overlap the light blocking area BA. The light blocking layer BL may block light incident to the light blocking layer BL. Accordingly, the light blocking layer BL can prevent color mixing between the first light emitting area EA1, the second light emitting area EA2, and the third light emitting area EA3. An opening overlapping each of the first light emitting area EA1, the second light emitting area EA2, and the third light emitting area EA3 may be defined in the light blocking layer BL. In an embodiment, for example, the light blocking layer BL may include an organic material and/or an inorganic material containing a black pigment, black dye, or the like.

The reflection control layer RCL may be disposed on the protective layer PL. The reflection control layer RCL may cover the light blocking layer BL. As the display device 100 includes the reflection control layer RCL, the display device 100 may not include a polarizer. That is, the reflection control layer RCL may replace the function of the polarizer. In other words, the reflection control layer RCL can selectively absorb external light reflected from the inside of the display device 100 according to a wavelength, thereby preventing light efficiency of the display device 100 from deteriorating.

In an embodiment, the reflection control layer RCL may include an inorganic material or an organic material containing a dye, a pigment, or a combination thereof.

In an embodiment, for example, the maximum absorption wavelength of the reflection control layer RCL may include a wavelength range of about 530 nm to about 600 nm. That is, the reflection control layer RCL may absorb light having a wavelength outside the wavelength range of red light, green light, or blue light emitted from the first, second, and third light emitting elements LED1, LED2, and LED3.

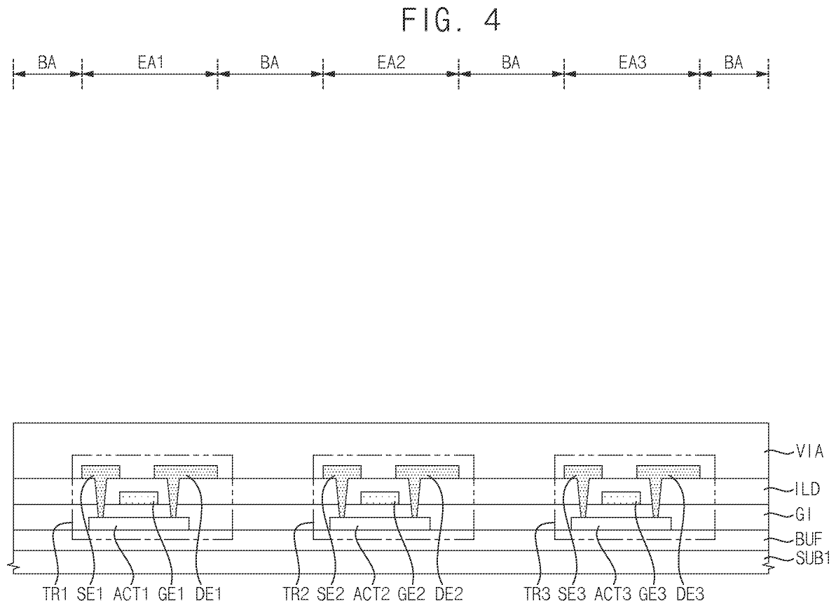

FIGS. 4, 5, 6, 7, 8, and 9 are cross-sectional views for explaining a method for manufacturing the display device of FIG. 2.

Referring to FIG. 4, the buffer layer BUF, the first, second, and third active patterns ACT1, ACT2, and ACT3, the gate insulating layer GI, the first, second, and third gate electrodes GET, GE2, and GE3, the interlayer-insulating layer ILD, the first, second, and third source electrodes SET, SE2, and SE3, the first, second, and third drain electrodes DE1, DE2, and DE3, and the via-insulating layer VIA may be formed sequentially on the substrate SUB.

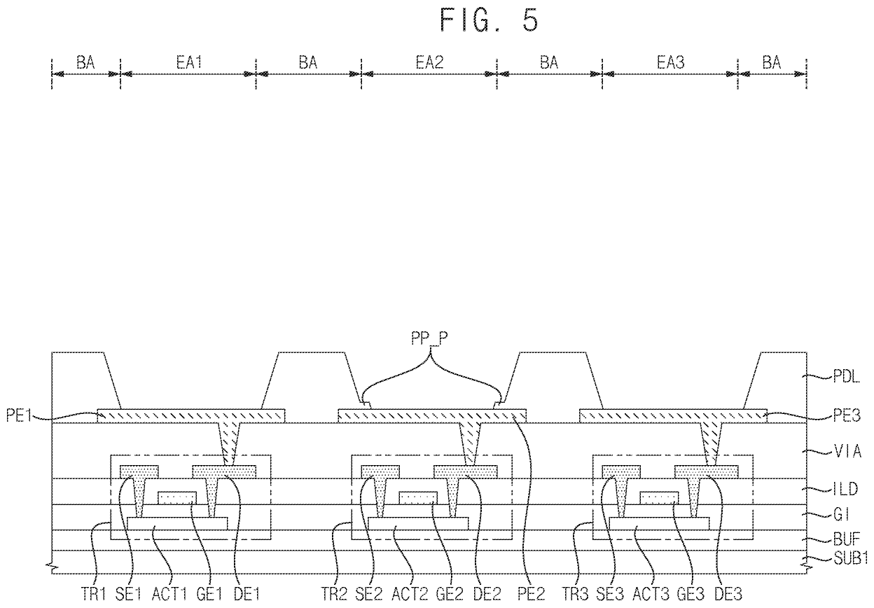

Referring to FIG. 5, the first, second, and third pixel electrodes PET, PE2, and PE3 may be formed on the via-insulating layer VIA. The first pixel electrode PET may be formed in the first light emitting area EAT, the second pixel electrode PE2 may be formed in the second light emitting area EA2, and the third pixel electrode PE3 may be formed in the third light emitting area EA3.

The pixel defining layer PDL may be formed on the via-insulating layer VIA. The pixel defining layer PDL may be formed in the light blocking area BA. A pixel opening exposing at least a part of the upper surface of each of the first, second, and third pixel electrodes PET, PE2, and PE3 may be formed in the pixel defining layer PDL. In an embodiment, in the second light emitting area EA2, a protruding part PP_P that contacts the second pixel electrode PE2 and protrudes toward the pixel opening may be formed in the pixel defining layer PDL.

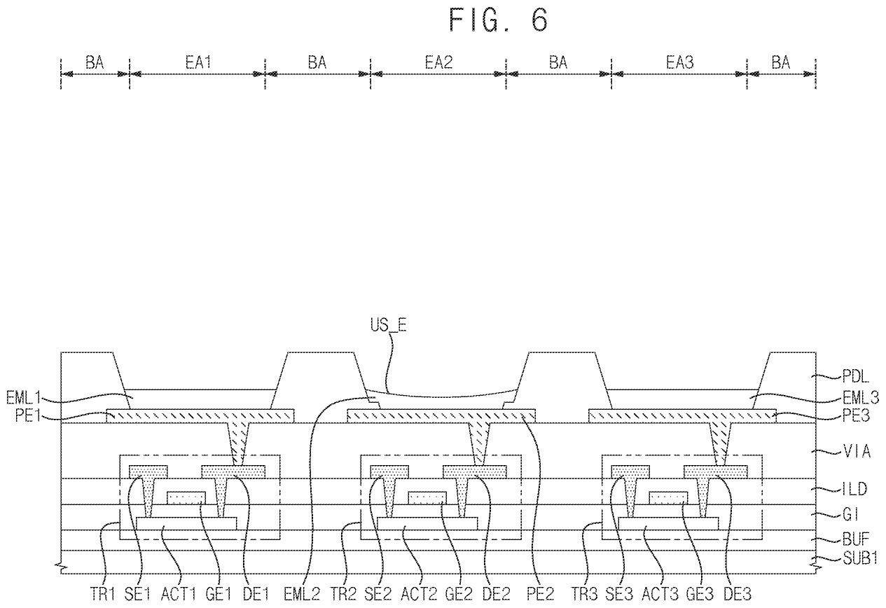

Referring to FIG. 6, the first light emitting layer EML1 may be formed on the first pixel electrode PET, the second light emitting layer EML2 may be formed on the second pixel electrode PE2, and the third pixel electrode PE3 may be formed on the third light emitting layer EML3. Specifically, the first, second, and third light emitting layers EML1, EML2, and EML3 may be formed in the pixel opening. In this case, the upper surface US_E of the second light emitting layer EML2 may be formed in a curved shape (e.g., a convex shape) by the protruding part PP_P of the pixel defining layer PDL in the cross-section. In an embodiment, for example, each of the first, second, and third light emitting layers EML1, EML2, and EML3 may be formed using an organic light emitting material that emits predetermined light.

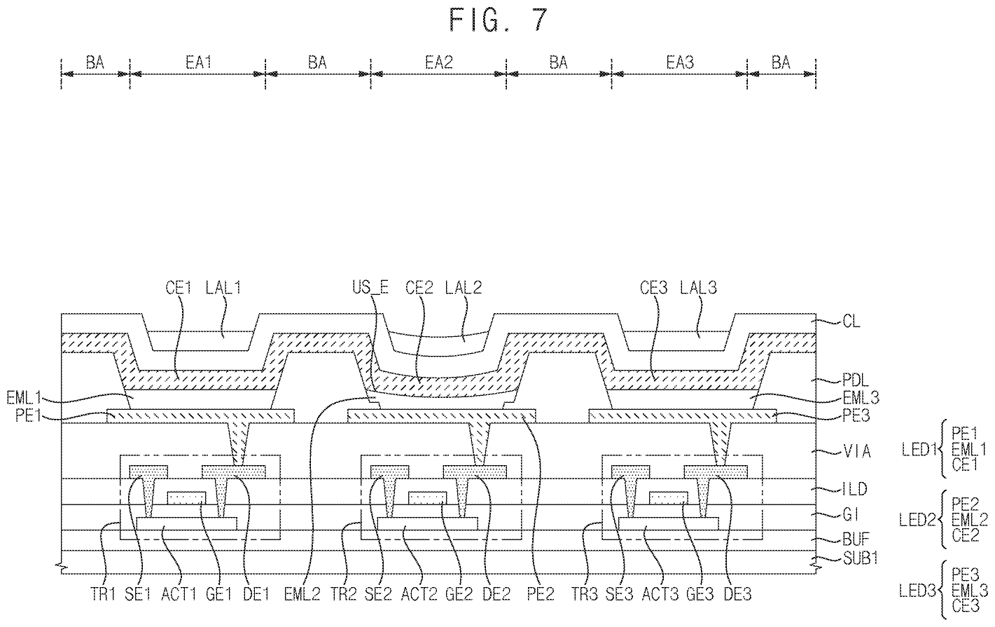

Referring to FIG. 7, the first, second, and third common electrodes CET, CE2, and CE3 may be formed on the first, second, and third light emitting layers EML1, EML2, and EML3 and the pixel defining layer PDL. The first, second, and third common electrodes CET, CE2, and CE3 may be integrally formed and may be formed on the whole surface of the display area DA.

The capping layer CL may be formed on the first, second, and third common electrodes CE1, CE2, and CE3. In an embodiment, for example, the capping layer CL may be formed using an organic material and/or an inorganic material.

The first, second, and third low-reflection inorganic layers LAL1, LAL2, and LAL3 may be formed on the capping layer CL. Specifically, the first low-reflection inorganic layer LAL1 may be formed in the first light emitting area EAT, the second low-reflection inorganic layer LAL2 may be formed in the second light emitting area EA2, and the third low-reflection inorganic layer LAL3 may be formed in the third light emitting area EA3. In an embodiment, for example, each of the first, second, and third low-reflection inorganic layers LAL1, LAL2, and LAL3 may be formed of a metal, a silicon compound, a metal oxide, or the like.

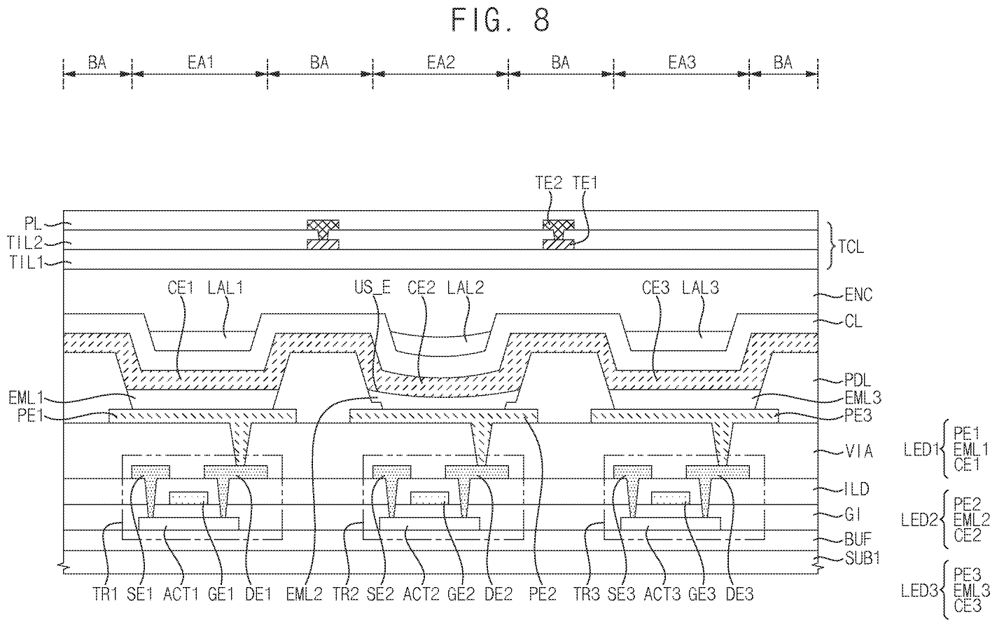

Referring to FIG. 8, the encapsulation layer ENC may be formed on the capping layer CL and the first, second, and third low-reflection inorganic layers LAL1, LAL2, and LAL3. In an embodiment, for example, the encapsulation layer ENC may include at least one inorganic encapsulation layer and at least one organic encapsulation layer.

The first touch insulating layer TIL1 may be formed on the encapsulation layer ENC. In an embodiment, for example, the first touch insulating layer TIL1 may be formed using an inorganic material. The first touch electrode TE1 may be formed on the first touch insulating layer TIL1.

The second touch insulating layer TIL2 may be formed on the first touch insulating layer TIL1 and the first touch electrode TE1. In an embodiment, for example, the second touch insulating layer TIL2 may be formed using an inorganic material.

The second touch electrode TE2 may be formed on the second touch insulating layer TIL2. The second touch electrode TE2 may be connected to the first touch electrode TE1 through a contact hole formed by removing a part of the second touch insulating layer TIL2.

The protective layer PL may be formed on the second touch insulating layer TIL2 and the second touch electrode TE2. In an embodiment, for example, the protective layer PL may be formed using an inorganic material.

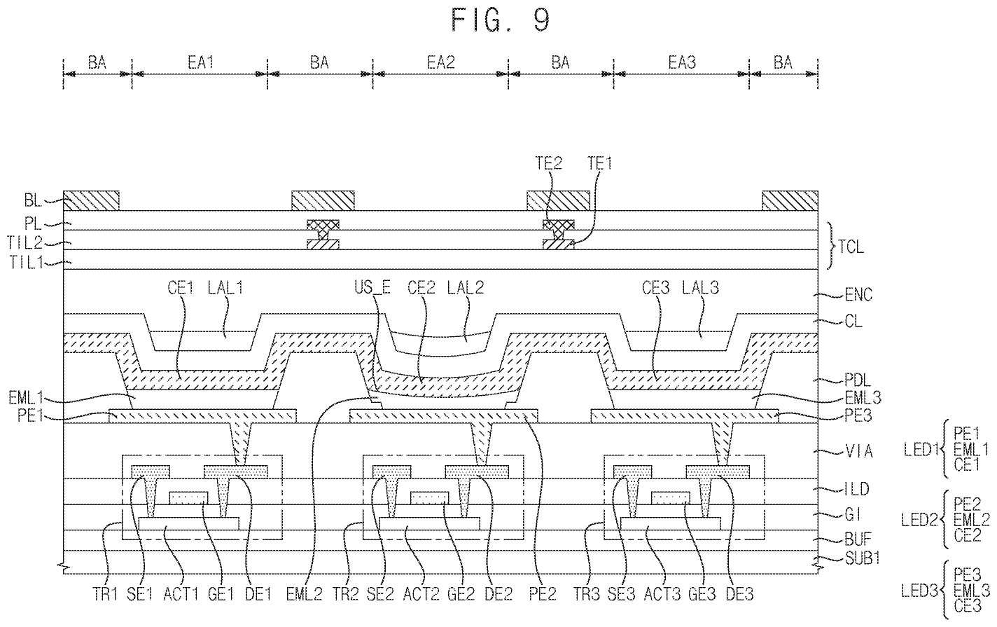

Referring to FIG. 9, the light blocking layer BL may be formed in the light blocking area BA on the protective layer PL. In an embodiment, for example, the light blocking layer BL may be formed using an inorganic material and/or an organic material containing a light blocking material such as black pigment, black dye, or the like.

Referring back to FIG. 2, the reflection control layer RCL may be formed on the touch sensing layer TCL. The reflection control layer RCL may cover the light blocking layer BL. In an embodiment, for example, the reflection control layer RCL may be formed using an inorganic material or an organic material containing dye, pigment, or combinations thereof.

Accordingly, the display device 100 illustrated in FIG. 2 may be manufactured.

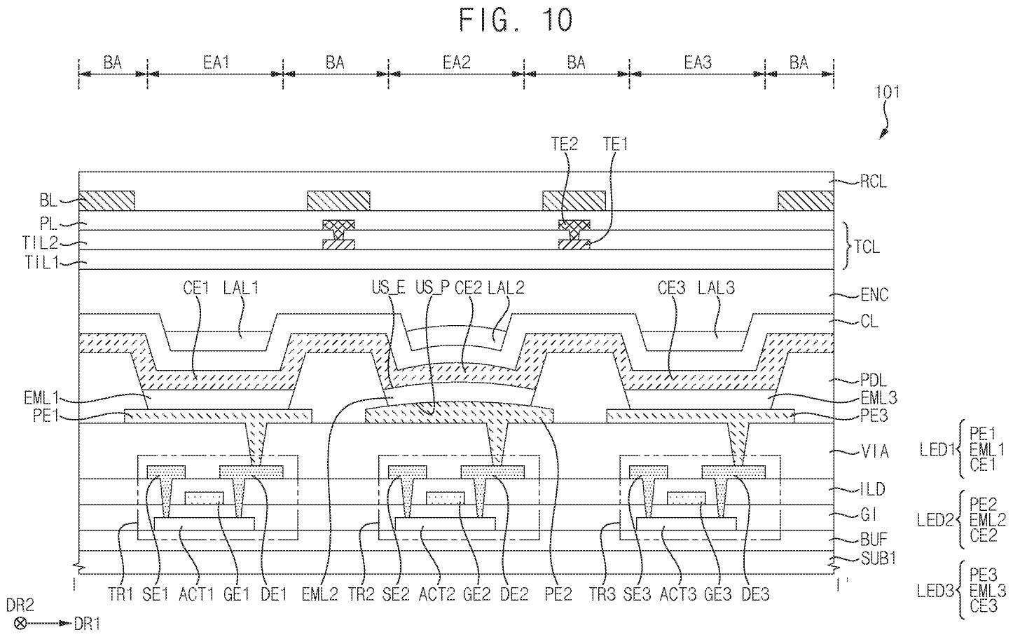

FIG. 10 is a cross-sectional view illustrating a display device according to another embodiment of the present disclosure.

Referring to FIG. 10, a display device 101 according to another embodiment of the present disclosure may include the substrate SUB, the buffer layer BUF, the gate insulating layer GI, the first, second, and third transistors TR1, TR2, and TR3, the interlayer-insulating layer ILD, the via-insulating layer VIA, the pixel defining layer PDL, the first, second, and third light emitting elements LED1, LED2, and LED3, the capping layer CL, the first, second, and third low-reflection inorganic layers LAL1, LAL2, and LAL3, the encapsulation layer ENC, the touch sensing layer TCL, the light blocking layer BL, and the reflection control layer RCL. However, the display device 101 described with reference to FIG. 10 may be substantially the same as or similar to the display device 100 described with reference to FIG. 2 except for the second pixel electrode PE2. In the following, redundant descriptions are omitted or simplified.

In an embodiment, the second pixel electrode PE2 may include an upper surface US_P having a curved shape in the cross-section. In detail, an edge of the upper surface US_P of the second pixel electrode PE2 may be inclined with respect to the substrate SUB.

In an embodiment, for example, the upper surface US_P of the second pixel electrode PE2 may have a convex curved shape in the cross-section. Alternatively, the upper surface US_P of the second pixel electrode PE2 may have a concave curved shape in cross section. However, embodiments of the present disclosure are not limited thereto. Alternatively, the upper surface US_P of the second pixel electrode PE2 may include a flat part positioned at the center and substantially flat, and an inclined part positioned at an edge and extending to have a predetermined slope from the flat part.

That is, as the second pixel electrode PE2 includes the upper surface US_P having a curved shape, the second light emitting layer EML2 may have a curved shape. In other words, the second light emitting layer EML2 may be disposed along the profile of the upper surface US_P of the second pixel electrode PE2.

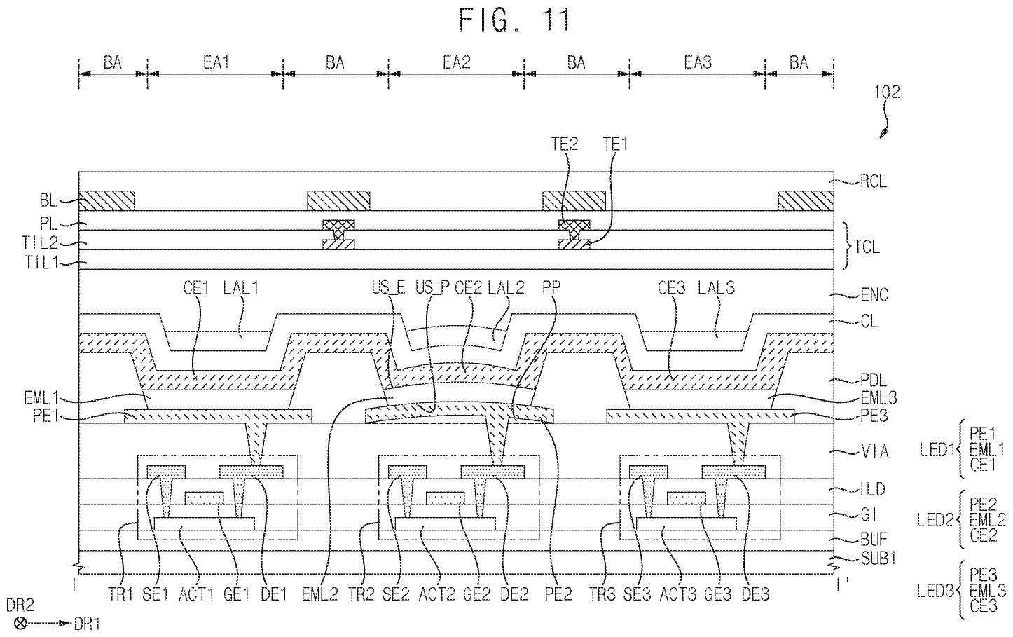

FIG. 11 is a cross-sectional view illustrating a display device according to still another embodiment of the present disclosure.

Referring to FIG. 11, a display device 102 according to still another embodiment of the present disclosure may include the substrate SUB, the buffer layer BUF, the gate insulating layer GI, the first, second, and third transistors TR1, TR2, and TR3, the interlayer-insulating layer ILD, the via-insulating layer VIA, the pixel defining layer PDL, the first, second, and third light emitting elements LED1, LED2, and LED3, the capping layer CL, the first, second, and third low-reflection inorganic layers LAL1, LAL2, and LAL3, the encapsulation layer ENC, the touch sensing layer TCL, the light blocking layer BL, and the reflection control layer RCL. However, the display device 102 described with reference to FIG. 11 may be substantially the same as or similar to the display device 101 described with reference to FIG. 10 except for the via-insulating layer VIA. In the following, redundant descriptions are omitted or simplified.

In the second light emitting area EA2, a part of the via-insulating layer VIA may protrude or be depressed. In an embodiment, in the second light emitting area EA2, the via-insulating layer VIA may include a protruding part PP protruding toward the second pixel electrode PE2 at an upper surface of the via-insulating layer VIA. For example, the upper surface of the protruding part PP may have a convex curved shape in the cross-section. Alternatively, the upper surface of the protruding part PP may include a flat part positioned at the center and substantially flat, and an inclined part positioned at an edge and extending to have a predetermined slope from the flat part.

That is, as the via-insulating layer VIA includes the protruding part PP overlapping the second light emitting area EA2, each of the second pixel electrode PE2 and the second light emitting layer EML2 may have a curved shape (e.g., a convex shape). In other words, each of the second pixel electrode PE2 and the second light emitting layer EML2 may be disposed along the profile of the protruding part PP of the via-insulating layer VIA.

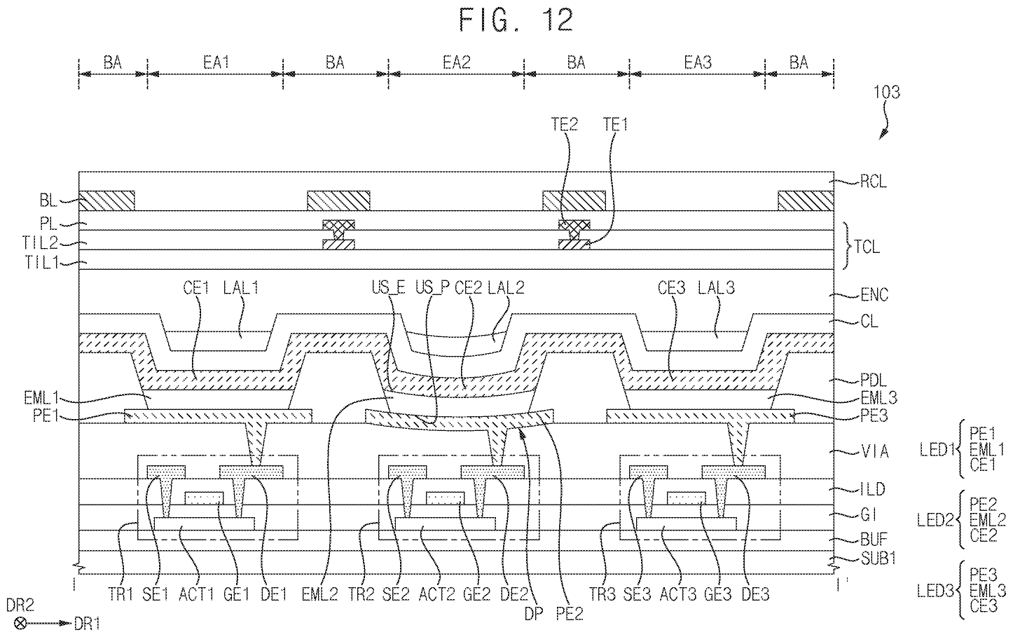

FIG. 12 is a cross-sectional view illustrating a display device according to still another embodiment of the present disclosure.

Referring to FIG. 12, a display device 103 according to still another embodiment of the present disclosure may include the substrate SUB, the buffer layer BUF, the gate insulating layer GI, the first, second, and third transistors TR1, TR2, and TR3, the interlayer-insulating layer ILD, the via-insulating layer VIA, the pixel defining layer PDL, the first, second, and third light emitting elements LED1, LED2, and LED3, the capping layer CL, the first, second, and third low-reflection inorganic layers LAL1, LAL2, and LAL3, the encapsulation layer ENC, the touch sensing layer TCL, the light blocking layer BL, and the reflection control layer RCL. However, the display device 103 described with reference to FIG. 12 may be substantially the same as or similar to the display device 102 described with reference to FIG. 11 except for the via-insulating layer VIA, the second pixel electrode PE2, and the second light emitting layer EML2. In the following, redundant descriptions are omitted or simplified.

In the second light emitting area EA2, a part of the via-insulating layer VIA may be depressed. In an embodiment, in the second light emitting area EA2, the via-insulating layer VIA may include a depressed part DP depressed toward the substrate SUB at an upper surface of the via-insulating layer VIA. For example, the upper surface of the depressed part DP may have a concave curved shape in the cross-section. Alternatively, the upper surface of the depressed part DP may include a flat part positioned at the center and substantially flat, and an inclined part positioned at an edge and extending to have a predetermined slope from the flat part.

That is, as the via-insulating layer VIA includes the depressed part DP overlapping the second light emitting area EA2, each of the second pixel electrode PE2 and the second light emitting layer EML2 may have a curved shape (e.g., concave shape) in the cross-section. In other words, each of the second pixel electrode PE2 and the second light emitting layer EML2 may be disposed along the profile of the depressed part DP of the via-insulating layer VIA.

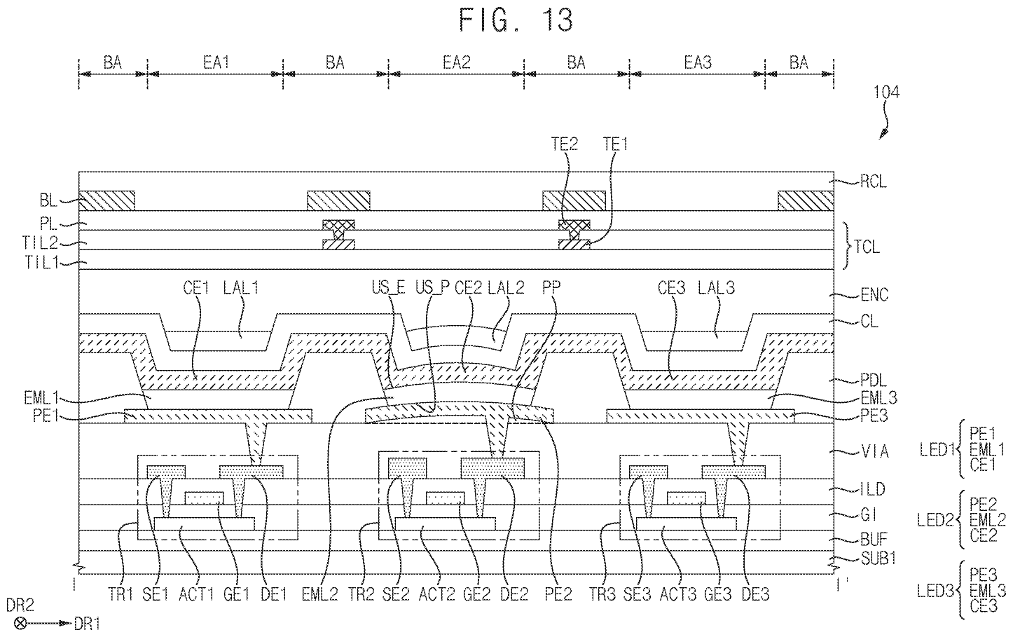

FIG. 13 is a cross-sectional view illustrating a display device according to still another embodiment of the present disclosure.

Referring to FIG. 13, a display device 104 according to still another embodiment of the present disclosure may include the substrate SUB, the buffer layer BUF, the gate insulating layer GI, the first, second, and third transistors TR1, TR2, and TR3, the interlayer-insulating layer ILD, the via-insulating layer VIA, the pixel defining layer PDL, the first, second, and third light emitting elements LED1, LED2, and LED3, the capping layer CL, the first, second, and third low-reflection inorganic layers LAL1, LAL2, and LAL3, the encapsulation layer ENC, the touch sensing layer TCL, the light blocking layer BL, and the reflection control layer RCL. However, the display device 104 described with reference to FIG. 13 may be substantially the same as or similar to the display device 102 described with reference to FIG. 11 except for the second source electrode SE2 and the second drain electrode DE2. In the following, redundant descriptions are omitted or simplified.

In an embodiment, when the second source electrode SE2 and the second drain electrode DE2 at least partially overlap the second light emitting layer EML2 in a plan view, a thickness of each of the second source electrode SE2 and the second drain electrode DE2 may be different from a thicknesses of each of the first source electrode SE1, the first drain electrode DE1, the third source electrode SE3, and the third drain electrode DE3.

In an embodiment, for example, the thicknesses of each of the second source electrode SE2 and the second drain electrode DE2 may be thicker than the thickness of each of the first source electrode SE1, the first drain electrode DE1, the third source electrode SE3, and the third drain electrode DE3. In this case, the via-insulating layer VIA may include the protruding part PP overlapping the second light emitting area EA2, and each of the second pixel electrode PE2 and the second light emitting layer EML2 may have a convex shape in the cross-section.

Alternatively, the thicknesses of each of the second source electrode SE2 and the second drain electrode DE2 may be thinner than the thickness of each of the first source electrode SE1, the first drain electrode DE1, the third source electrode SE3, and the third drain electrode DE3. In this case, the via-insulating layer VIA may include a depressed part (e.g., the depressed part DP of FIG. 12) overlapping the second light emitting area EA2, and each of the second pixel electrode PE2 and the second light emitting layers EML2 may have a concave shape in the cross-section.

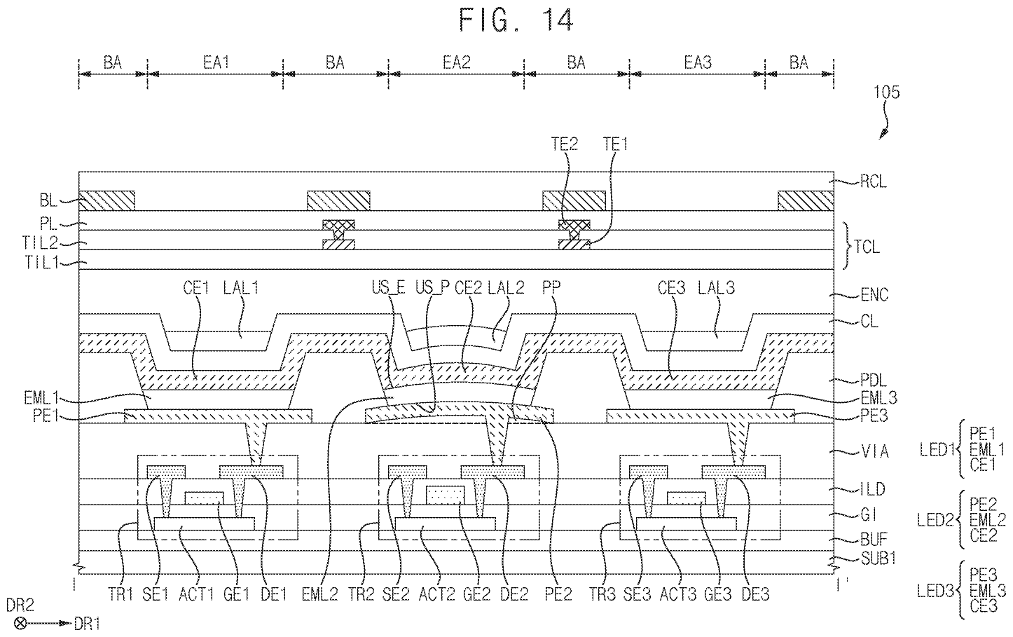

FIG. 14 is a cross-sectional view illustrating a display device according to still another embodiment of the present disclosure.

Referring to FIG. 14, a display device 105 according to still another embodiment of the present disclosure may include the substrate SUB, the buffer layer BUF, the gate insulating layer GI, the first, second, and third transistors TR1, TR2, and TR3, the interlayer-insulating layer ILD, the via-insulating layer VIA, the pixel defining layer PDL, the first, second, and third light emitting elements LED1, LED2, and LED3, the capping layer CL, the first, second, and third low-reflection inorganic layers LAL1, LAL2, and LAL3, the encapsulation layer ENC, the touch sensing layer TCL, the light blocking layer BL, and the reflection control layer RCL. However, the display device 105 described with reference to FIG. 14 may be substantially the same as or similar to the display device 102 described with reference to FIG. 11 except for the second gate electrode GE2. In the following, redundant descriptions are omitted or simplified.

In an embodiment, when the second gate electrode GE2 at least partially overlaps the second light emitting layer EML2 in a plan view, a thickness of the second gate electrode GE2 may be different from a thickness of each of the first and third gate electrodes GE1 and GE3.

In an embodiment, for example, the thickness of the second gate electrode GE2 may be thicker than the thickness of each of the first and third gate electrodes GET and GE3. In this case, the via-insulating layer VIA may include a protruding part overlapping the second light emitting area EA2, and each of the second pixel electrode PE2 and the second light emitting layer EML2 may have a convex shape in the cross-section.

Alternatively, the thickness of the second gate electrode GE2 may be thinner than the thickness of each of the first and third gate electrodes GET and GE3. In this case, the via-insulating layer VIA may include a depressed part (e.g., the depressed part DP of FIG. 12) overlapping the second light emitting area EA2, and each of the second pixel electrode PE2 and the second light emitting layers EML2 may have a concave shape in the cross-section.

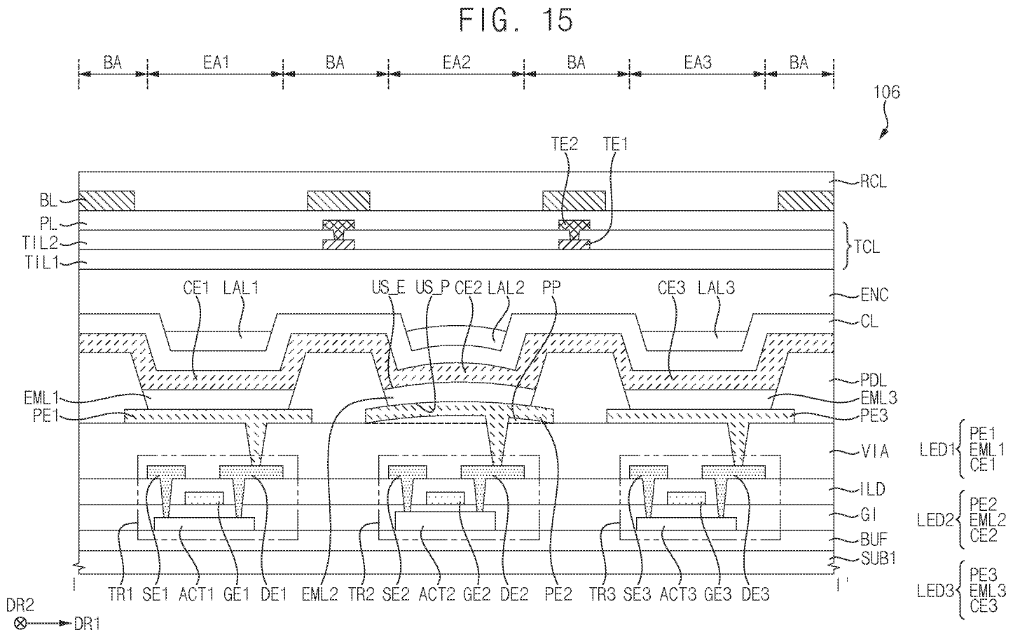

FIG. 15 is a cross-sectional view illustrating a display device according to still another embodiment of the present disclosure.

Referring to FIG. 15, a display device 106 according to still another embodiment of the present disclosure may include the substrate SUB, the buffer layer BUF, the gate insulating layer GI, the first, second, and third transistors TR1, TR2, and TR3, the interlayer-insulating layer ILD, the via-insulating layer VIA, the pixel defining layer PDL, the first, second, and third light emitting elements LED1, LED2, and LED3, the capping layer CL, the first, second, and third low-reflection inorganic layers LAL1, LAL2, and LAL3, the encapsulation layer ENC, the touch sensing layer TCL, the light blocking layer BL, and the reflection control layer RCL. However, the display device 106 described with reference to FIG. 15 may be substantially the same as or similar to the display device 102 described with reference to FIG. 11 except for the second active pattern ACT2. In the following, redundant descriptions are omitted or simplified.

In an embodiment, when the second active pattern ACT2 at least partially overlaps the second light emitting layer EML2 in a plan view, the thickness of the second active pattern ACT2 may be different from a thickness of each of the first and third emitting layers EML1 and EML3.

In an embodiment, for example, a thickness of the second active pattern ACT2 may be thicker than a thickness of each of the first and third active patterns ACT1 and ACT3. In this case, the via-insulating layer VIA may include the protruding part PP overlapping the second light emitting area EA2, and each of the second pixel electrode PE2 and the second light emitting layer EML2 may have a convex shape in the cross-section.

Alternatively, the thickness of the second active pattern ACT2 may be thinner than each of the first and third active patterns ACT1 and ACT3. In this case, the via-insulating layer VIA may include a depressed part (e.g., the depressed part DP of FIG. 12) overlapping the second light emitting area EA2 and each of the second pixel electrode PE2 and the second light emitting layers EML2 may have a concave shape in the cross-section.

Referring again to FIGS. 2, 3, and 10 to 15, in the display devices 100, 101, 102, 103, 104, 105, and 106 according to the embodiments, the upper surface US_E of the second light emitting layer EML2 that emits green light may have a curved shape in the cross-section, and the upper surface of each of the first light emitting layer EML1 that emits red light and the third light emitting layer EML3 that emits blue light may be substantially flat. Accordingly, the amount of light emitted from the second light emitting layer EML2 at a low angle can be increased, and the color of an image displayed in the display area DA can be prevented from reddish. In this case, display quality of the display devices 100, 101, 102, 103, 104, 105, and 106 can be effectively improved.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present invention. Accordingly, all such modifications are intended to be included within the scope of the present invention as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a substrate including a first light emitting area, a second light emitting area, and a third light emitting area, and a light blocking area positioned between the first, second, and third light emitting areas;
a first light emitting layer disposed in the first light emitting area on the substrate and which emits light of a first color;
a second light emitting layer disposed in the second light emitting area on the substrate, including an upper surface having a curved shape in a cross-section, and which emits light of a second color different from the first color;
a third light emitting layer disposed in the third light emitting area on the substrate and which emits light of a third color different from the first and second colors; and
a reflection control layer disposed on the first, second, and third light emitting layers.

2. The display device of claim 1, wherein an edge of the upper surface of the second light emitting layer is inclined with respect to a major upper surface of the substrate.

3. The display device of claim 1, wherein the upper surface of the second light emitting layer has a concave shape or a convex shape in the cross-section.

4. The display device of claim 1, wherein each of the first and third light emitting layers has a substantially flat upper surface.

5. The display device of claim 1, further comprising:
a first pixel electrode disposed in the first light emitting area between the substrate and the first light emitting layer;
a second pixel electrode disposed in the second light emitting area between the substrate and the second light emitting layer; and
a third pixel electrode disposed in the third light emitting area between the substrate and the third light emitting layer,
wherein the second pixel electrode has an upper surface having a curved shape in the cross-section.

6. The display device of claim 5, further comprising:
a via-insulating layer disposed between the substrate and the first, second, and third pixel electrodes,
wherein in the second light emitting area, the via-insulating layer includes a protruding part protruding toward the second pixel electrode at an upper surface of the via-insulating layer.

7. The display device of claim 5, further comprising:
a via-insulating layer disposed between the substrate and the first, second, and third pixel electrodes,
wherein in the second light emitting area, the via-insulating layer includes a depressed part depressed toward the substrate at an upper surface of the via-insulating layer.

8. The display device of claim 5, further comprising:
a first transistor electrically connected to the first pixel electrode and including a first active pattern, a first gate electrode, a first source electrode, and a first drain electrode;
a second transistor electrically connected to the second pixel electrode and including a second active pattern, a second gate electrode, a second source electrode, and a second drain electrode; and
a third transistor electrically connected to the third pixel electrode and including a third active pattern, a third gate electrode, a third source electrode, and a third drain electrode.

9. The display device of claim 8, wherein when the second source electrode and the second drain electrode at least partially overlap the second light emitting layer in a plan view,
a thickness of each of the second source electrode and the second drain electrode is different from a thickness of each of the first source electrode, the first drain electrode, the third source electrode, and the third drain electrode.

10. The display device of claim 8, wherein when the second gate electrode at least partially overlap the second light emitting layer,
a thickness of the second gate electrode is different from a thickness of each of the first and third gate electrodes.

11. The display device of claim 8, wherein when the second active pattern at least partially overlap the second light emitting layer,
a thickness of the second active pattern is different from a thickness of each of the first and third active patterns.

12. The display device of claim 1, wherein the first color is red, the second color is green, and the third color is blue.

13. The display device of claim 1, wherein the reflection control layer includes an inorganic material or an organic material containing at least one selected from a group consisting of dye and pigment.

14. The display device of claim 1, further comprising:
a reflection-reducing inorganic layer disposed on the first, second, and third light emitting layers and including an inorganic material.

15. The display device of claim 1, further comprising:
an encapsulation layer disposed on the first, second, and third light emitting layers and including: a first inorganic encapsulation layer including sequentially disposed first, second, third, and fourth sub-layers, an organic encapsulation layer disposed on the first inorganic encapsulation layer, and a second inorganic encapsulation layer disposed on the organic encapsulation layer.

16. The display device of claim 15, wherein the first sub-layer includes silicon nitride, each of the second, third, and fourth sub-layers includes silicon oxynitride, and the second inorganic encapsulation layer includes silicon oxynitride.

17. The display device of claim 1, further comprising:
a light blocking layer disposed in the light blocking area on the substrate and covered by the reflection control layer.

18. A display device comprising:
a substrate including a first light emitting area, a second light emitting area, and a third light emitting area, and a light blocking area positioned between the first, second, and third light emitting areas;
a first light emitting layer disposed in the first light emitting area on the substrate, including a substantially flat upper surface, and which emits light of a red color;
a second light emitting layer disposed in the second light emitting area on the substrate, including an upper surface having a curved shape in a cross-section, and which emits light of a green color;
a third light emitting layer disposed in the third light emitting area on the substrate, including a substantially flat upper surface, and which emits light of a blue color;
an encapsulation layer disposed on the first, second, and third light emitting layers;
a touch sensing layer disposed on the encapsulation layer and including a first touch electrode and a second touch electrode connected to the first touch electrode; and
a reflection control layer disposed on the touch sensing layer.

19. The display device of claim 18, wherein an edge of the upper surface of the second light emitting layer is inclined with respect to a major upper surface of the substrate.

20. The display device of claim 18, wherein the upper surface of the second light emitting layer has a concave shape or a convex shape in the cross-section.
